(19) United States
(12) Patent Application Publication
(10) Pub. No.: US 2019/0271877 A1
(43) Pub. Date: Sep. 5, 2019

(54) DISPLAYS

(71) Applicant: FlexEnable Limited, Cambridge (GB)

(72) Inventor: Charlotte Harrison, Cambridge (GB)

(21) Appl. No.: 16/286,717

(22) Filed: Feb. 27, 2019

(30) Foreign Application Priority Data
Mar. 5, 2018 (GB) 1803487.6

(51) Int. Cl. G02F 1/1335; G02F 1/1339; H01L 51/52

(52) U.S. Cl. CPC G02F 1/133512; G02F 1/1339; H01L 51/52; G02F 2201/56; G02F 1/1368; G02F 2001/133567; G02F 2001/13398; G02F 2001/133565; G02F 2001/133562

(57) ABSTRACT

A display for mounting on a curved surface. The display includes a display stack comprising a substrate to conform to a curved surface; a pixelated display medium on the substrate; and a parallax barrier. The parallax barrier may comprise a pattern of light blocking elements to restrict viewing of pixels of the display medium to a viewing angle. In some implementations the parallax barrier may be configured so that positions of the light blocking elements, with respect to the pixels, change with lateral position on the display.

### RELATED APPLICATIONS

The present invention is a U.S. National Stage under 35 USC 371 patent application, claiming priority to UK Serial No. 1803487.6, filed on 5 Mar. 2018, the entirety of which is incorporated herein by reference.

### FIELD OF THE INVENTION

The invention generally relates to flexible/curved displays.

### BACKGROUND TO THE INVENTION

There are many applications for curved displays and for displays which are flexible so that they may be conformed to a curved surface. These include conforming a display to the curved interior surface of a vehicle for displaying information to the driver and/or one or more passengers; and consumer electronic devices (CEDs) such as mobile phones, tablets, televisions and other devices with display screens.

Depending upon the application there may be a need to restrict the viewing angle of a curved display, for example for privacy or so that the driver of a vehicle, or a passenger, is not distracted. It may also be desirable to provide a bright, uniform display for a particular viewing direction, which may impose different but related requirements.

### SUMMARY OF THE INVENTION

In one aspect a display for mounting on a curved surface includes a display stack comprising: a substrate to conform to a curved surface; a pixelated display medium on the substrate; and a parallax barrier. The parallax barrier may comprise a pattern of light blocking elements to restrict viewing of pixels of the display medium to a viewing angle.

In some implementations the parallax barrier is configured so that positions of the light blocking elements, with respect to the pixels, change with lateral position on the display. This can improve the effectiveness of the parallax barrier in limiting the viewing angle for a curved display.

Examples of such a display are able to restrict the viewing angle of a flexible or curved display when, for example, it is mounted on a curved surface. The particular displacements of the light blocking elements away from a nominal position, which may for example be when an element is centered over a pixel, depend on the degree to which the display is curved, or configured to be curved when in use.

In implementations, by changing the positions of the light blocking elements, more particularly the lateral positions or “in plane” positions of these elements, with location on the display the light blocking elements may be aligned with respect to a local viewing direction which changes with lateral position on the display in accordance with curvature of a surface of the display.

There are two effects which may contribute to different degrees. First, for a particular viewing direction the position of a light blocking element with respect to a pixel of the display medium can change as the surface of the display is tilted with respect to the viewing direction, because the light blocking elements are generally slightly displaced in a vertical direction away from the display medium. Second the viewing direction changes according to which lateral location on the (curved) display is viewed. The changing positions of the light blocking elements may compensate for one or both these effects.

Thus in some implementations the positions of the light blocking elements with respect to the pixels change with lateral position on the display to compensate for a change in viewing angle (with respect to the display) with lateral position on the display when the display is mounted on the curved surface.

In some implementations the positions of the light blocking elements with respect to the pixels are increasingly offset from an initial relative position at an initial location with increasing lateral distance across the display from the initial location. The initial location may be at the centre of the display in one or two dimensions, or towards or at an edge of the display, depending upon the intended location of the viewer with respect to the display. The initial relative position may be a position where a light blocking element is centered on a pixel, for example where design viewing angle is at 90 degrees to the surface of the display at the initial location. Alternatively a light blocking element may be displaced away from the lateral centre of a pixel of the display medium at the initial location.

The display may be curved, for example pre-curved to fit onto a curved surface and/or the display may be flexible. The curvature may be curvature in one or two dimensions.

Where the curvature is in one dimension the light blocking elements may comprise stripes with a distance from one strip to an adjacent defined by a stripe pitch. The pixels may have a pixel pitch in the same direction as the stripe pitch. The stripe pitch may be less than the pixel pitch to account for changing lateral positions of the stripes across the display.

Where the curvature is in two dimensions the positions of the light blocking elements with respect to the pixels may change with lateral position on the display in two orthogonal directions. The light blocking elements may define 2D frames around the pixels having windows, to define the viewing angle in 2D.

The parallax barrier may be in front of or behind the pixelated display medium. For example where the display medium is an LCD display medium with a backlight the parallax barrier may be in front of the display medium or between the backlight and the display medium. Alternatively, where the display medium is an LCD display medium the parallax barrier may be between an upper or front side of the substrate and a polarising layer of the LCD display.

Where the display medium is an LCD display medium there may be two substrates, a first substrate bearing a thin film transistor (TFT) backplane and electrodes, a second substrate bearing the display medium. In such a structure the two substrates may sandwich the TFT and display medium layers. The first substrate may have a first polariser on the opposite side of the substrate to the TFT layer. The second substrate may have a second polariser on the opposite side of the substrate to the display medium. The parallax barrier may be between the first substrate and the TFT/electrode layer and/or between the second substrate and the second polariser. A layer of the LCD display medium may include spacers to define a thickness of the layer. In this case the parallax barrier may be integrated with the spacers; that is in some implementations the spacers may also function as the parallax barrier, or vice-versa.

Where the display medium is an emissive display medium such as an organic light emitting diode display medium the parallax barrier may be in front of the display medium.

The wherein the light blocking elements may comprise black resin, which is advantageous in being non-reflective; or they may comprise metal.

In another aspect there is provided a method of displaying information over a limited viewing angle using a curved display. The method comprises providing a parallax barrier for the display, the parallax barrier comprising a pattern of light blocking elements to restrict viewing of pixels of the display to a viewing angle.

The method may further comprise compensating for a change in viewing angle with respect to lateral position on the curved display by laterally positioning the light blocking elements.

Further aspects of the method may be as previously described with reference to the display.

The method may comprise displaying information on a curved surface such as a curved surface inside a vehicle, for example a pillar of the vehicle; or on a curved surface of a consumer electronic device.

A vehicle may be provided with a camera to capture an image of the external environment and part or all of the captured image may then be reproduced on the curved display to increase visibility for the driver. This may give the impression that a part of the vehicle, such as an A-pillar, is partially or wholly transparent. In such a use case it is beneficial to ensure that the image, which is tailored for the driver, is not seen by a passenger as the view would be distorted and distracting.

### BRIEF DESCRIPTION OF THE DRAWINGS

Embodiments of the invention will be described, by way of example, with reference to the accompanying drawings, in which:

FIGS. 1a and 1b show example display stacks;

FIG. 2 shows a cross-sectional schematic view of a display incorporating a parallax barrier; and

FIGS. 3a to 3c show, respectively, first and second example parallax barriers for the display of FIG. 2, and an offset parallax barrier for an off-axis pixel.

### DETAILED DESCRIPTION OF EMBODIMENTS

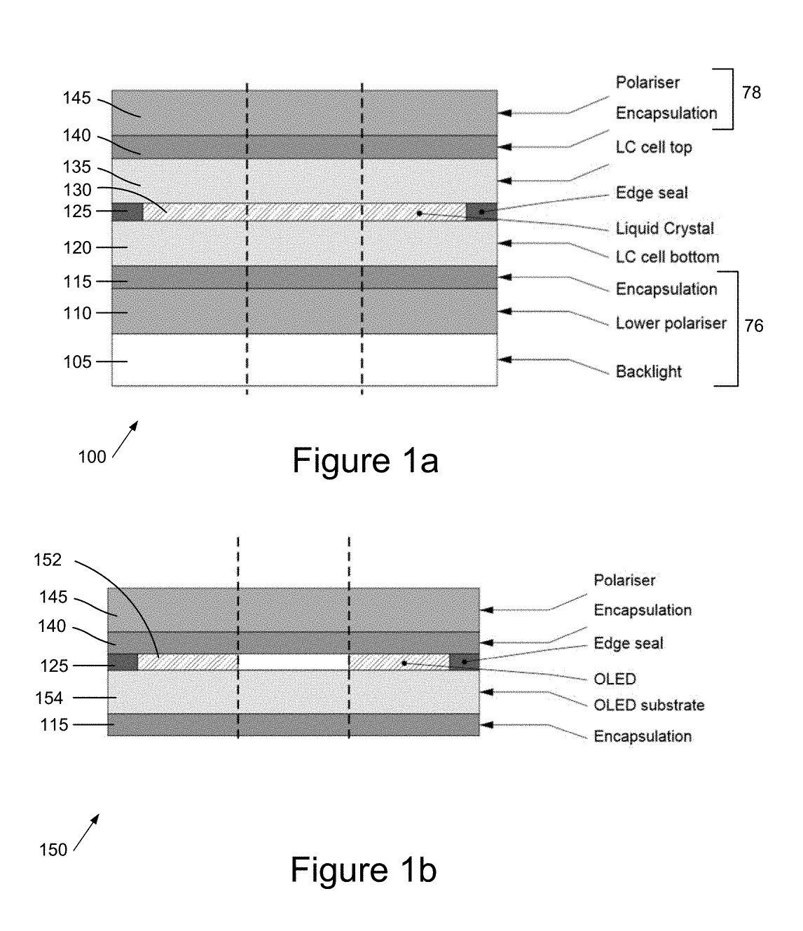

FIG. 1a illustrates a schematic cross-sectional view of an example display stack 100 of a liquid crystal display, which may be an OLCD (Organic LCD) display, where the TFTs are organic. In this example display stack the liquid crystal (LC) material 130 is disposed between a bottom (or first) encapsulation layer 115 and a top (or second) encapsulation layer 140. The LC material 130 is sandwiched by a LC cell top layer 135 and a LC cell bottom layer 120. An edge seal 125 is provided on both sides of the LC material 130. The LC layers are generally driven by control circuitry (not shown), for example, thin film transistors (TFTs) and associated electrical connections, disposed on the LC cell bottom 120. The control circuitry generally includes an array of thin film transistors (TFTs). In the case of OLCD (Organic LCD), where the TFTs are organic, the encapsulation layer 115 may be a thin film.

In the structure of FIG. 1a, a first polariser film or layer 110 is provided below the bottom encapsulation layer 115. A backlight layer 105 is provided below the first polariser film 110. The bottom encapsulation layer 115 could generally be a glass substrate. In the example of FIG. 1 which is an OLCD, the LC cell bottom 120 and LC cell top 140 are generally made of TAC (Cellulose Triacetate). The bottom encapsulation layer 115 may include an indium tin oxide (ITO) layer (not shown). The bottom encapsulation layer 115 and the first polariser film 110 generally form part of a driver component 76 of the display structure 100. The backlight layer 105 is generally a separate part from the display stack.

In the structure of FIG. 1a, a second polariser film 145 is provided on the top encapsulation layer 140. In one example, one side of the top encapsulation layer 140 there may be provided a colour filter layer (not shown); this may reside on the “LC cell top” layer 135. The encapsulation layer 140 may not be required if the “LC cell Top” is made of glass but in the case of an OLCD is generally present. The encapsulation film 140 could be integrated into the polariser 145 or “LC cell top” layer 135. The second polariser film 145, the top encapsulation layer 140 generally form part of a colour filter component 78 of the structure 100. The top encapsulation layer 140 is may be a glass substrate or may be a flexible organic-inorganic barrier, for example, in OLCDs.

FIG. 1b illustrates a schematic cross-sectional view of an example display stack 150 of an OLED (Organic Light Emitting Diode) display. The LCD display medium is replaced by OLED display medium 152 on substrate 154. The polariser is optional.

In each of FIGS. 1a and 1b the display and substrate(s) may be curved, for example fabricated from curved glass, or may be flexible, for example fabricated from plastic and employing organic TFTs. Details of suitable technology can be found on the Applicant's web site and in the Applicant's earlier published patent applications.

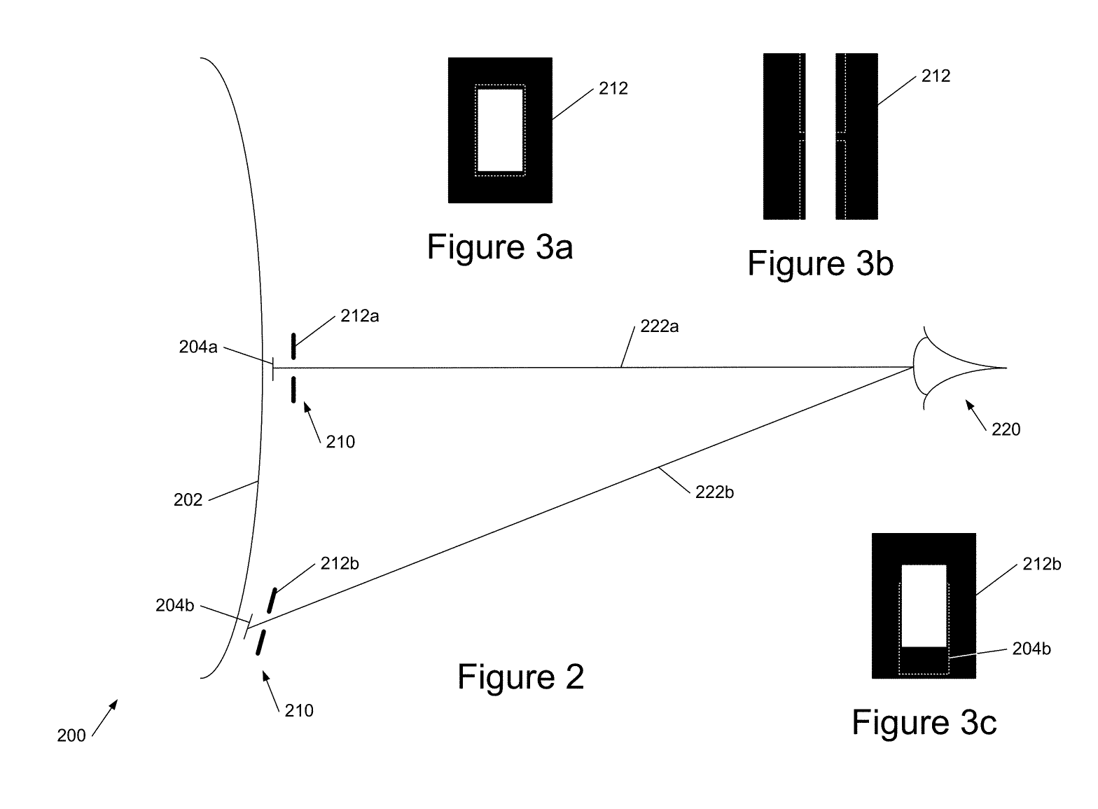

FIG. 2 shows a cross-sectional schematic view of a curved display 200 comprising a curved/flexible substrate 202 and having a plurality of display medium pixels 204 of which two 204a,b are shown. The display may comprise a display stack as previously described.

The display 200 of FIG. 2 includes a parallax barrier 210 comprising a plurality of light blocking elements 212 of which two 212a,b are shown. As shown in FIG. 3b, to limit viewing in one direction the parallax barrier may comprise stripes defining longitudinal windows over the pixels. As shown in FIG. 3a, to limit viewing in two directions the parallax barrier may comprise rectangular windows over each pixel.

A viewer 220 sees different parts of the display from different angles with respect to the surface of the display because of the curvature of the display. For example as illustrated the viewer sees a central part of the display straight-on, that is with a viewing direction 222a at 90 degrees to the central part of the display. However the same viewer sees the edge of the display at an acute angle, that is viewing direction 222b makes an acute angle to the surface of the display at the edge of the display. It will be appreciated that in general the viewing angles differ even when the central part of the display is viewed obliquely rather than straight-on.

The light blocking element 212a of the parallax barrier is arranged to obscure pixel 204a from viewing at angles beyond those defined by a viewing cone (or triangular prism for a 1D shield). This is approximately defined by the locations of the edges of light blocking element 212a—beyond the viewing cone light blocking element 212a obscures the pixel 204a from view. The pixel has a finite lateral extent and thus the blocking is gradual rather than immediate—from some intermediate angles a viewer may see part of the pixel, and thus a dimmed display.

In a similar way the light blocking element 212b of the parallax barrier is arranged to obscure pixel 204b from viewing at angles beyond those defined by the same viewing cone (or triangular prism). However because of the change in viewing direction to direction 222b the position of light blocking element 212b with respect to the underlying pixel 204b is preferably laterally shifted towards the centre of the display. This shift may be in one or two directions, depending upon whether the display is curved in one or two directions.

There may be one light blocking element per pixel. However the relative positions of these elements with respect to the underlying pixels may gradually shift across the display. They may have a slightly different pitch to the underlying pixels.

FIGS. 3a and 3b show example light blocking element shapes for 2D and 1D viewing angle limitation respectively. The underlying pixel is shown dashed. The position of the dashed regions with respect to the mask changes with lateral position on the display. FIG. 3c shows the pixel 204b offset with respect to the light blocking element 212b.

In the stack of FIG. 1a the parallax barrier may be located, for example, between layers 135 and 140 or 140 and 145; or between layers 120 and 130.

In general the parallax barrier may advantageously be formed in a planarising layer of the stack. For example for a viewing distance of order 1 metre the distance between the parallax barrier and pixel may be around 1-50 μm, or 1-10 μm. These distances are such that the parallax barrier may be formed is/using a planarising layer.

In some implementations liquid crystal layer 130 may include spacers. Potentially the parallax barrier and spacers may be integrated.

The light blocking elements may comprise metal but to reduce reflections black resin is preferable. A thickness in the range 0.1-1 μm may be suitable for a metal barrier; a black resin barrier may have a thickness in the range 0.8-3 μm, for example around 1 μm)

Applications of the technology include, but are not limited to, in-vehicle displays, mobile phone/tablet displays, and ATM (Automated Teller Machine) displays.

No doubt many other effective alternatives will occur to the skilled person. It will be understood that the invention is not limited to the described embodiments and encompasses modifications apparent to those skilled in the art lying within the spirit and scope of the claims appended hereto.

1. A display for mounting on a curved surface, the display having a display stack comprising:
a substrate to conform to a curved surface;
a pixelated display medium on the substrate; and
a parallax barrier;
wherein the parallax barrier comprises a pattern of light blocking elements to restrict viewing of pixels of the display medium to a viewing angle.

2. A display as claimed in claim 1, wherein the positions of the light blocking elements with respect to the pixels change with lateral position on the display.

3. A display as claimed in claim 1, wherein the positions of the light blocking elements with respect to the pixels change with lateral position on the display to compensate for a change in viewing angle with lateral position on the display when the display is mounted on the curved surface.

4. A display as claimed in claim 1, wherein the positions of the light blocking elements with respect to the pixels are increasingly offset from an initial relative position at an initial location with increasing lateral distance across the display from the initial location.

5. A display as claimed in claim 4, wherein the initial location is at a central lateral position on the display and/or wherein the initial relative position is a position where a light blocking element is centered on a pixel.

6. A display as claimed in claim 1, wherein the light blocking elements comprise stripes with a distance from one strip to an adjacent defined by a stripe pitch, wherein the pixels have a pixel pitch in the same direction as the stripe pitch, and wherein the stripe pitch is less than the pixel pitch.

7. A display as claimed in claim 1, wherein the curved surface curves in two dimensions, and wherein the positions of the light blocking elements with respect to the pixels change with lateral position on the display in two orthogonal directions.

8. A display as claimed in claim 7, wherein the light blocking elements define 2D frames around the pixels having windows defining the viewing angle in 2D.

9. A display as claimed in claim 1, wherein the parallax barrier is located between the pixelated display medium and a front surface of the display.

10. A display as claimed in claim 1, wherein the display has a light source behind the display, and wherein parallax barrier is located between the light source and the pixelated display medium.

11. A display as claimed in claim 1, wherein the pixelated display medium comprises a layer of LCD display medium including spacers to define a thickness of the layer of LCD display medium, and wherein the parallax barrier is integrated with the spacers.

12. A display as claimed in claim 1, wherein the light blocking elements comprise black resin.

13. A method of displaying information over a limited viewing angle using a curved display, the method comprising:
providing a parallax barrier for the display comprising a pattern of light blocking elements to restrict viewing of pixels of the display to a viewing angle

14. A method as claimed in claim 13 further comprising:
compensating for a change in viewing angle with respect to lateral position on the curved display by laterally positioning the light blocking elements.
